(19) United States
(12) Patent Application Publication
(10) Pub. No.: US 2015/0200245 A1
(43) Pub. Date: Jul. 16, 2015

(54) LATERAL METAL INSULATOR METAL (MIM) CAPACITOR WITH HIGH-Q AND REDUCED AREA

(71) Applicant: QUALCOMM Incorporated, San Diego, CA (US)

(72) Inventors: Changhan Hobie YUN, San Diego, CA (US); Daeik Daniel KIM, San Diego, CA (US); Chengjie ZUO, Santee, CA (US); Mario Francisco VELEZ, San Diego, CA (US); Jonghae KIM, San Diego, CA (US); David Francis BERDY, San Diego, CA (US)

(73) Assignee: QUALCOMM Incorporated, San Diego, CA (US)

(21) Appl. No.: 14/153,917

(22) Filed: Jan. 13, 2014

(51) Int. Cl. H01L 49/02

(52) U.S. Cl. CPC H01L 28/88; H01L 28/10

(57) ABSTRACT

A lateral metal insulator metal (MIM) capacitor includes a first conductive plate, and a dielectric layer on a sidewall(s) and a first surface of the first conductive plate adjacent to the sidewall(s). The capacitor also includes a second conductive plate on a portion of the dielectric layer that is on the sidewall(s) and on a portion of the dielectric layer that covers a portion of the first surface of the first conductive plate. A sidewall capacitance is also greater than a surface capacitance of the capacitor.

### TECHNICAL FIELD

The present disclosure generally relates to the fabrication of integrated circuits (ICs). More specifically, the present disclosure relates to a lateral metal insulator metal (MIM) capacitor with high Q (or quality factor) and reduced area.

### BACKGROUND

The process flow for semiconductor fabrication of integrated circuits (ICs) may include front-end-of-line (FEOL), mid-of-line (MOL), and back-end-of-line (BEOL) processes. The front-end-of-line process may include wafer preparation, isolation, well formation, gate patterning, spacer, extension and source/drain implantation, silicide formation, and dual stress liner formation. The mid-of-line process may include gate contact formation. The back-end-of-line processes may include a series of wafer processing steps for interconnecting the semiconductor devices created during the front-end-of-line and mid-of-line processes. Successful fabrication and qualification of modern semiconductor chip products involves an interplay between the materials and the processes employed. In particular, the formation of conductive material plating for the semiconductor fabrication in the back-end-of-line processes is an increasingly challenging part of the process flow. This is particularly true in terms of maintaining a small feature size while reducing parasitics and loss to achieve high performance devices. The same challenge of maintaining a small feature size while achieving high performance also applies to passive on glass (POG) technology, where components such as inductors and capacitors are built upon a highly insulative substrate that may also have a very low loss. A key challenge for passive on glass technology is to reduce parasitic components and improve the quality factor (Q).

### SUMMARY

In one aspect of the present disclosure, a lateral metal insulator metal (MIM) capacitor is described. The capacitor includes a first conductive plate and a dielectric layer on a sidewall and a first surface of the first conductive plate that is adjacent to the sidewall. The capacitor also includes a second conductive plate on a portion of the dielectric layer that is on the sidewall and on a portion of the dielectric layer that covers a portion of the first surface of the first conductive plate. A sidewall capacitance is also greater than a surface capacitance of the capacitor.

In another aspect of the disclosure, a lateral metal insulator metal (MIM) capacitor is disclosed that includes first means for conducting. The capacitor also includes a dielectric layer on a sidewall and a first surface of the first conducting means adjacent to the sidewall. The capacitor also includes second means for conducting on a portion of the dielectric layer that is on the sidewall and on a portion of the dielectric layer that covers a portion of the second surface of the first conducting means. A sidewall capacitance is greater than a surface capacitance of the capacitor.

In a further aspect of the disclosure, a back end of line processing method to fabricate a lateral metal insulator metal (MIM) capacitor is described. The method includes patterning a first conductive layer that is deposited on a substrate. The method also includes depositing a dielectric layer on the first conductive layer so that the dielectric layer is on a sidewall of the first conductive layer and a first surface of the first conductive layer adjacent to the sidewall of the first conductive layer. The method further includes depositing a second conductive layer on a portion of the dielectric layer that is on the sidewall and on a portion of the dielectric layer that covers a portion of the first surface of the first conductive layer. A sidewall capacitance is greater than a surface capacitance of the capacitor.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 shows a cross-sectional view of a device with a typical metal insulator metal (MIM) capacitor.

FIG. 2 shows a cross-sectional view of a device with a typical passive on glass (POG) metal insulator metal (MIM) capacitor.

FIG. 3A shows a device with a typical metal insulator metal (MIM) capacitor having a thick bottom plate.

FIG. 3B shows a device with a typical metal oxide metal (MOM) capacitor.

FIG. 4 shows a device with a lateral metal insulator metal (MIM) capacitor, according to one aspect of the disclosure.

FIG. 5A shows a cross-sectional view of a device with a lateral metal insulator metal (MIM) capacitor without interconnects, according to one aspect of the disclosure.

FIG. 5B shows a cross-sectional view of a device with a lateral metal insulator metal (MIM) capacitor having interconnects, according to one aspect of the disclosure.

FIGS. 6A-6C show cross-sectional views illustrating steps of making a typical metal oxide metal (MOM) capacitor.

FIGS. 6D-6F show cross-sectional views illustrating steps of making a typical vertical metal insulator metal (MIM) capacitor.

FIGS. 7A-7C show cross-sectional views illustrating steps of making a lateral metal insulator metal (MIM) capacitor, according to one aspect of the disclosure.

FIG. 8A shows a more detailed cross-sectional view of a typical metal oxide metal (MOM) capacitor.

FIG. 8B shows a more detailed cross-sectional view of a typical vertical metal insulator metal (MIM) capacitor.

FIGS. 8C-8D show cross-sectional views of typical vertical metal insulator metal (MIM) capacitors with current flow.

FIG. 9 shows a more detailed cross-sectional view of a lateral metal insulator metal (MIM) capacitor, according to one aspect of the disclosure.

FIG. 10A shows a device with a low parasitic inductor-capacitor transition structure, according to one aspect of the disclosure.

FIG. 10B shows a device with a series of multiple lateral metal insulator metal (MIM) capacitors, according to one aspect of the disclosure.

FIG. 10C shows a device with at least two lateral metal insulator metal (MIM) capacitors in parallel or series, according to one aspect of the disclosure.

FIG. 10D shows a device with a lateral and a vertical metal insulator metal (MIM) capacitor in one structure, according to one aspect of the disclosure.

FIG. 11A shows a device with an under/overpass metal insulator metal (MIM) capacitor, according to one aspect of the disclosure.

FIGS. 11B-11D show different views of a device with a multi-finger lateral metal insulator metal (MIM) capacitor for both series and parallel connections, according to one aspect of the disclosure.

FIG. 12A is a top view illustrating the area of a typical planar metal insulator metal (MIM) capacitor.

FIG. 12B is a three-dimensional view illustrating the area of a lateral metal insulator metal (MIM) capacitor, according to one aspect of the disclosure.

FIG. 13 is a process flow diagram illustrating a process to fabricate a lateral metal insulator metal (MIM) capacitor, according to one aspect of the disclosure.

FIG. 14 is a block diagram showing an exemplary wireless communication system in which a configuration of the disclosure may be advantageously employed.

FIG. 15 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Provided is a lateral metal insulator metal (MIM) capacitor that has a number of advantages over conventional MIM capacitor designs. For example, the lateral MIM capacitor has a lower parasitic resistance and inductance, a high Q (or quality factor) and a higher capacitance density (e.g., smaller capacitor gaps), compared to a typical metal oxide metal (MOM) capacitor, for example. Lateral MIM capacitors also have a low electrostatic loss or low electrostatic resistance. This property, combined with the high Q and low area of a lateral MIM capacitor allows it to be arranged in a series connection to achieve a high electrostatic discharge (ESD) rating.

Passive on glass devices involve high-performance inductor and capacitor components that have a variety of advantages over other technologies, such as surface mount technology or multi-layer ceramic chips. These advantages include being more compact in size and having smaller manufacturing variations. Passive on glass devices also involve a higher Q factor value that meets stringent low insertion loss and low power consumption specifications.

Devices such as capacitors or standard vertical metal insulator metal (MIM) capacitors have high series resistance and inductance. Also, metal oxide metal (MOM) capacitors can potentially reduce resistance and inductance but have insufficient density.

Therefore, provided is a lateral MIM capacitor structure with low resistance and low inductance also having a high density that is more than sufficient for most high-speed or radio frequency (RF) applications. The lateral MIM capacitor also has a high Q factor and a low electrostatic resistance or loss. As a result, the lateral MIM capacitor can be arranged in series to achieve a high electrostatic discharge (ESD) rating. The lateral MIM capacitor also conserves significant amounts of area compared to conventional MIM capacitor designs, and is therefore a more compact design.

In one aspect of the disclosure, a lateral metal insulator metal (MIM) capacitor is disclosed that includes a first conductive plate, and at least one dielectric layer on at least one sidewall and a first surface of the first conductive plate adjacent to the sidewall(s). The capacitor also includes a second conductive plate on a portion of the dielectric layer that is on the sidewall and on a portion of the dielectric layer covering a portion of the first surface of the first conductive plate. A sidewall capacitance is greater than a surface capacitance.

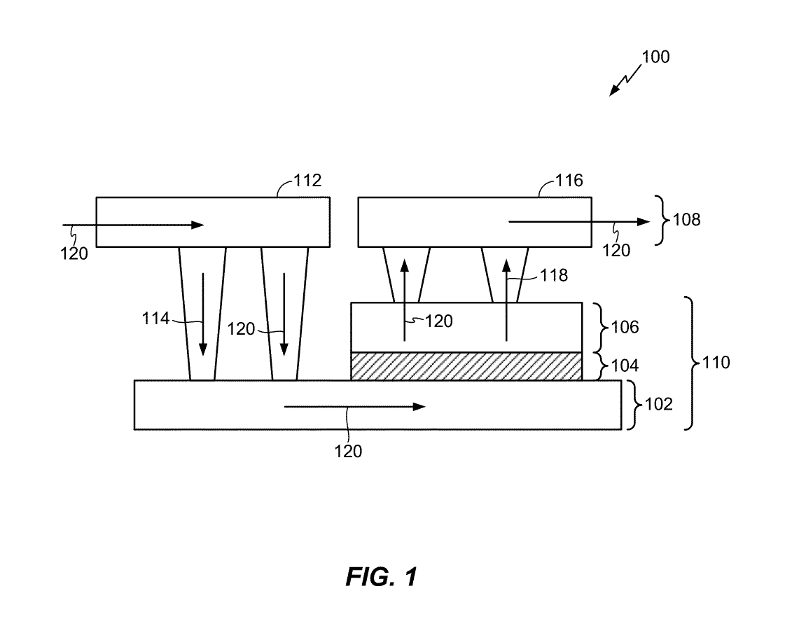

FIG. 1 shows a cross-sectional view of a device 100 with a typical metal insulator metal (MIM) capacitor 110. Device 100 shows a metal insulator metal (MIM) capacitor 110, made up of a capacitor bottom plate 102, a dielectric layer 104 and a capacitor top plate 106. The device 100 also shows a first conductive layer 112 and a first interconnect 114 coupled to the capacitor bottom plate 102, and a second conductive layer 116 and a second interconnect 118 coupled to the capacitor top plate 106. The current flow arrows 120 indicate the direction of current flow throughout various components in the device 100, such as the first conductive layer 112, the first interconnect 114, the MIM capacitor 110, the second conductive layer 116 and the second interconnect 118.

An issue with the MIM capacitor 110 shown in FIG. 1 is that it has a limited Q factor. The Q factor for a capacitor can be expressed by the equation Q=1/ωCR where w is the operating frequency of the capacitor (usually in radians per second), C is the capacitance, and R is the series or parasitic resistance of the capacitor. Therefore, the more series/parasitic resistance a capacitor has, the lower its Q factor will be. The first interconnect 114 and the second interconnect 118 also contribute to limiting the overall Q factor of the MIM capacitor 110.

Another issue with MIM capacitor 110 is that there may be limited conductance in the capacitor bottom plate 102, which is typically made of thin metal. An issue that also affects the overall efficiency of the MIM capacitor 110 is that there may be a long current path along any of the capacitor bottom plate 102 or the capacitor top plate 106, which leads to signal delay.

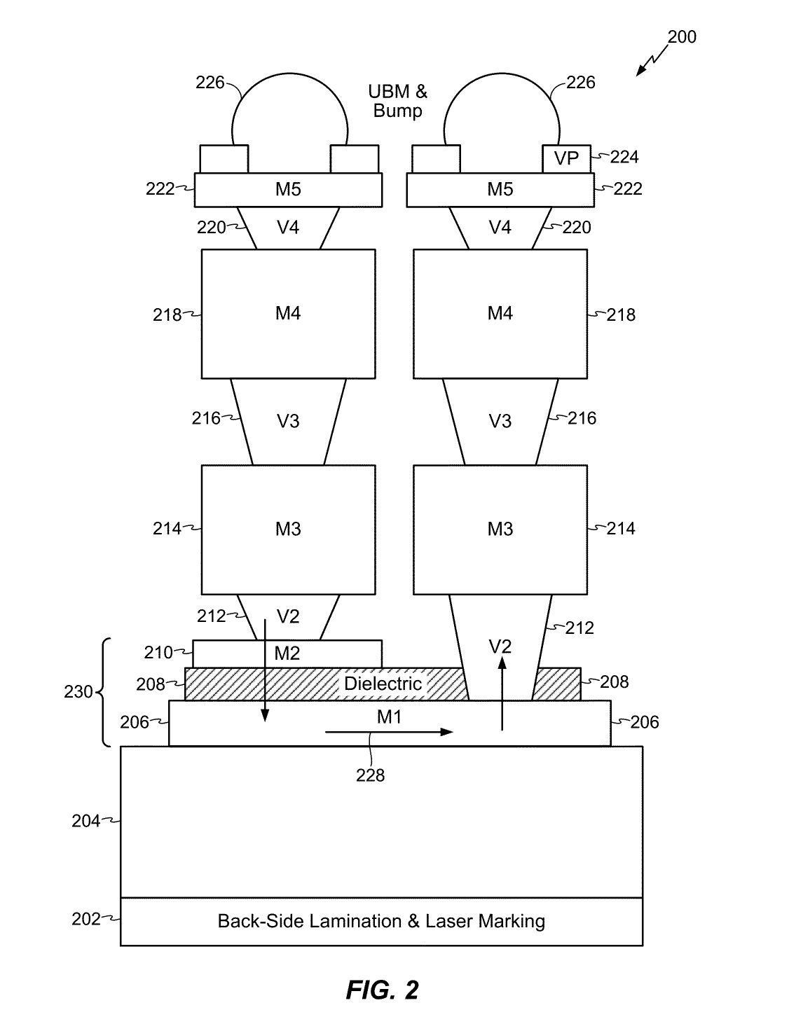

FIG. 2 shows a cross-sectional view of a device 200 with a typical passive on glass (POG) metal insulator metal (MIM) capacitor 230. The device 200 includes a back-side lamination and laser marking plate 202, a substrate 204, a first conductive layer 206, a dielectric layer 208, a second conductive layer 210, a first via 212, a third conductive layer 214, a second via 216, a fourth conductive layer 218, a third via 220, a fifth conductive layer 222, a passivation layer 224, and a solder bump 226. In the practice of under bump metallurgy (UBM), the passivation layer 224 helps hold the solder bumps 226 in place and protect the upper conductive layers 222. A metal insulator metal (MIM) capacitor 230 is formed from the first conductive layer 206, the dielectric layer 208 and the second conductive layer 210. The current flow arrows 228 also represent the direction of current flow through the various conductive layers, vias and the MIM capacitor 230.

An issue with the MIM capacitor 230 is that it has a limited Q factor because of all the vias or interconnects (e.g., vias 212, 216, 220). Another problem is that the longer bottom plate of the MIM capacitor 230, represented by the first conductive layer 206, which lengthens the current path, limits conductance and also leads to inefficiency in terms of current flow.

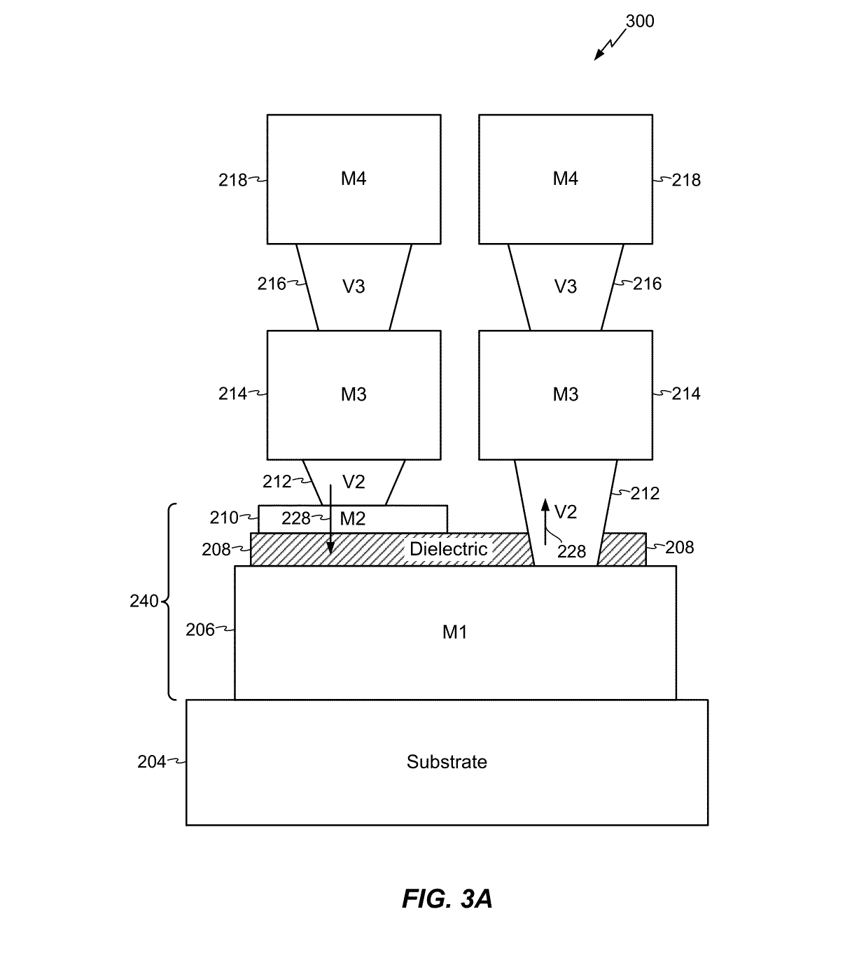

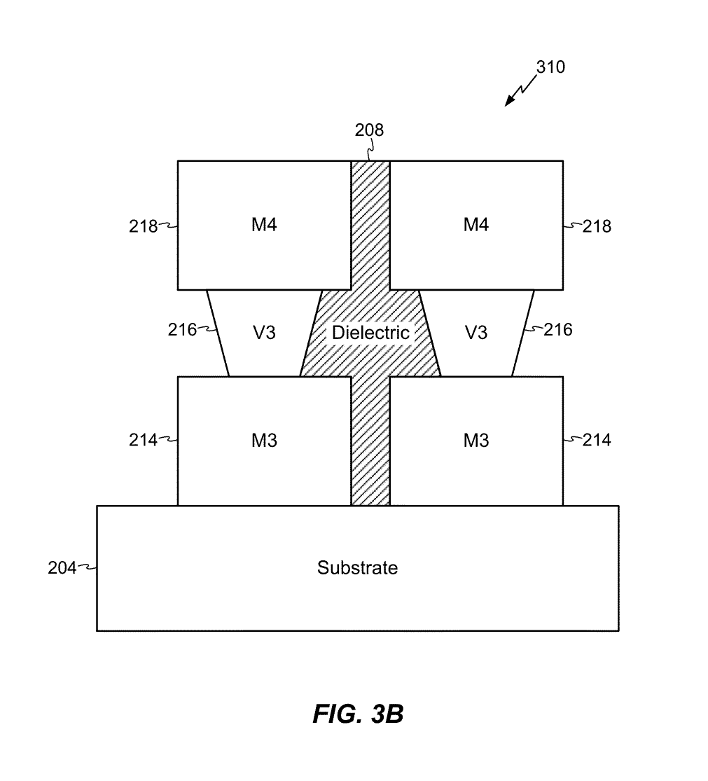

FIG. 3A shows a device 300 with a typical metal insulator metal (MIM) capacitor 240 having a thick bottom plate (of the first conductive layer 206). The MIM capacitor 240 shown in FIG. 3A is an attempt to solve the problems of the MIM capacitor 110 shown in FIG. 1 and the MIM capacitor 230 shown in FIG. 2. By having the first conductive layer 206 be a shorter and thicker bottom plate for the MIM capacitor 240, the current path is made shorter and thereby more efficient.

A problem with this design is that it is impractical to fabricate due to process difficulties (and scarcity of resources) in being able to deposit and pattern that thick of a first conductive layer 206. The Q or quality factor is also limited due to the various interconnects in the device 300, such as vias 212, 216, 220 (the same vias in FIG. 2). Therefore, the MIM capacitor 240 design in FIG. 3A is problematic and not a feasible solution.

FIG. 3B shows a device 310 with a typical metal oxide metal (MOM) capacitor 250. The device 310 includes a substrate 204, a third conductive layer 214, a second via 216, a fourth conductive layer 218 and a dielectric layer 208. However, the dielectric layer 208 fills a vertical space in between two stacks of metal. Therefore, a metal oxide metal (MOM) capacitor 250 is formed horizontally, in an orientation opposite to how most typical metal insulator metal (MIM) capacitors are formed.

A problem, however, with the MOM capacitor 250 is the low capacitance due to a larger capacitor gap, which may require a minimum trace spacing of 10 μm to 20 μm. This low capacitance value makes the MOM capacitor 250 unsuitable for radio frequency (RF) applications or high-speed applications that require higher capacitance values. The vias 216 also contribute to a lower Q, or quality factor for the MOM capacitor 250. Therefore, the MOM capacitor 250 design in FIG. 3B also is problematic.

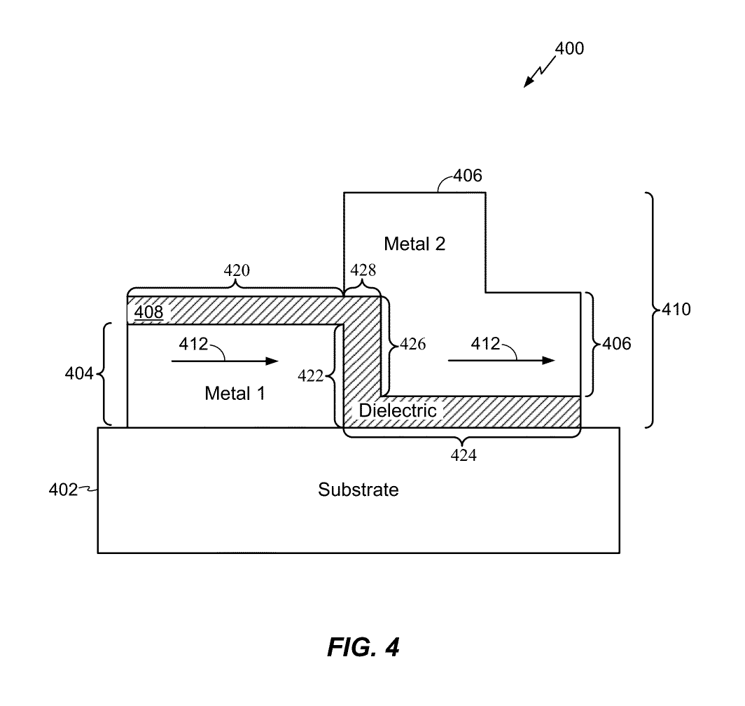

FIG. 4 shows a device 400 with a lateral metal insulator metal (MIM) capacitor 410, according to one aspect of the disclosure. The device 400 includes a substrate 402, a first conductive layer 404, a dielectric layer 408 and a second conductive layer 406. A lateral metal insulator metal (MIM) capacitor 410 is formed from the first conductive layer 404, the dielectric layer 408 and the second conductive layer 406. Current flow arrows 412 show the direction of current flow through the lateral MIM capacitor 410.

The dielectric layer 408 is deposited on a top surface 420 and a sidewall 422 of the first conductive layer 404. In this configuration, the dielectric layer 408 is also deposited on the substrate 402 to provide a bottom surface portion 424 of the dielectric layer 408. In this configuration, the second conductive layer 406 is deposited on a sidewall portion 428 and the bottom surface portion 424 of the dielectric layer 408 to efficiently use the space and area and also provide other beneficial properties. The sidewall capacitance (e.g., the capacitance between the dielectric layer 408 and the sidewall 422 of the first conductive layer 404 and the sidewall 426 of the second conductive layer 406) is greater than a surface capacitance (e.g., the capacitance between the dielectric layer 408 and the top surface 420 of the first conductive layer 404 and the bottom surface 428 of the second conductive layer 406).

In one configuration, the sidewall capacitance is increased by eliminating or reducing any overlap between the second conductive layer 406 and the first conductive layer 404. In this configuration, the second conductive layer 406 is only on a sidewall portion 428 and a bottom surface portion 424 of the dielectric layer 408. As a result, the second conductive layer does not overlap with the top surface 420 of the first conductive layer. In alternative configurations, any overlap between the second conductive layer 406 and the first conductive layer 404 is controlled so that the sidewall capacitance is greater than the surface capacitance.

Other beneficial properties of the design of the lateral MIM capacitor 410 include ultra-low parasitic or series resistance and inductance due to the thick metal layers of the first conductive layer 404 and the second conductive layer 406. In addition, because no vias are used in the design of the lateral MIM capacitor 410, the Q or quality factor is drastically improved. Further, because the current does not flow along a long capacitor plate, the current path is made shorter and more efficient, and conductance throughout the entirety of the lateral MIM capacitor 410 is also greatly improved.

The substrate 402 of may be made of glass or other materials such as silicon (Si), gallium arsenide (GaAs), indium phosphide (InP), silicon carbide (SiC), sapphire (Al2O3), quartz, silicon on Insulator (SOI), silicon on Sapphire (SOS), high resistivity silicon (HRS), aluminum nitride (AlN), a plastic substrate, a laminate, or a combination thereof.

The first conductive layer 404 and the second conductive layer 406 may be made of conductive material such as Copper (Cu), or other conductive materials with high conductivity such as Silver (Ag), Copper (Cu), Gold (Au), Aluminum (Al), Tungsten (W), Nickel (Ni), and other like materials.

The dielectric layer 408 may be made of PVD or CVD oxide, such as Silicon Dioxide (SiO2). To reduce the parasitic inductance of a high Q capacitor, materials having a low k, or a low dielectric constant value, are preferred for the dielectric layer 408. Exemplary dielectric layer include, but are not limited to, doped silicon dioxide (SiO2), or its fluorine-doped, carbon-doped, porous and porous carbon-doped forms, as well as spin-on organic polymeric dielectrics such as polyimide (PI), polynorbornenes, benzocyclobutene (BCB), polytetrafluoroethylene (PTFE) and spin-on silicone based polymeric dielectrics.

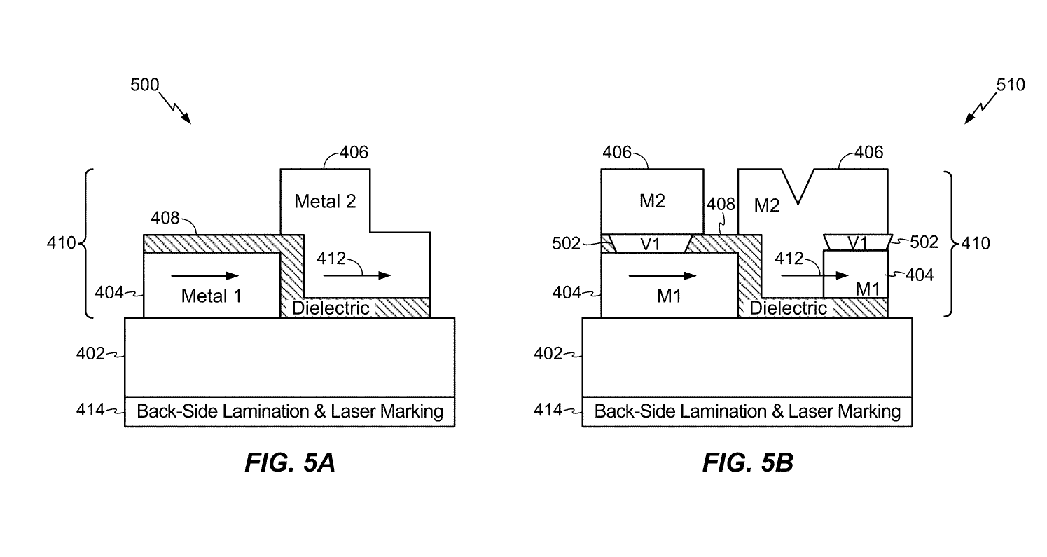

FIG. 5A shows a cross-sectional view of a device 500 with a lateral metal insulator metal (MIM) capacitor 410 without interconnects, according to one aspect of the disclosure. The device 500 is similar to the device 400 of FIG. 4, the difference being that in device 500, there is a back-side lamination and laser marking plate 414. The device 500 of FIG. 5A is also different from the device 510 of FIG. 5B in that the device 500 of FIG. 5A does not have interconnects or vias placed within it.

FIG. 5B shows a cross-sectional view of a device 510 with a lateral metal insulator metal (MIM) capacitor 410 having interconnects 502, according to one aspect of the disclosure. The device 510 shows the lateral MIM capacitor 410 with interconnects 502 installed. Although the placement of interconnects may decrease the Q factor in a typical MIM capacitor design, the placement of interconnects 502 with the lateral MIM capacitor 410 design does not impact the Q factor as much because one, there are only a few interconnects 502, and two, they stay on the same level and do not continuously stack vertically, as in devices with typical MIM capacitor designs.

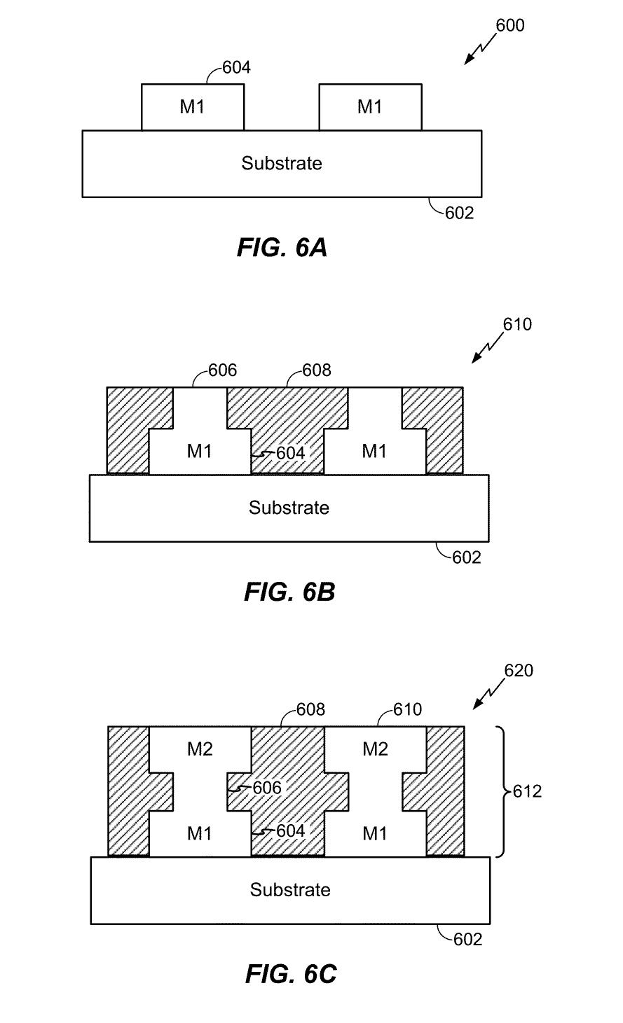

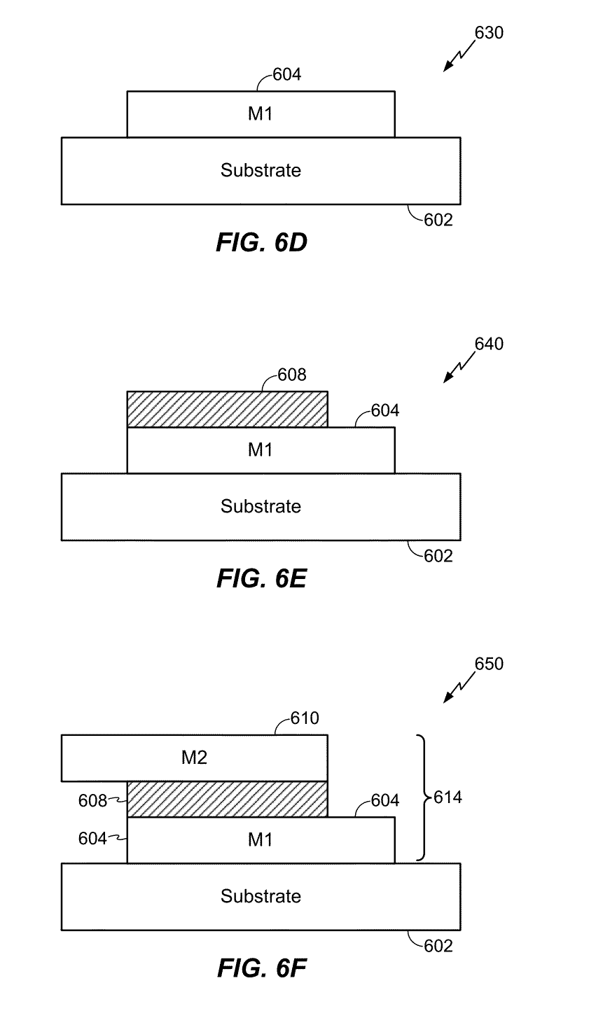

FIGS. 6A-6C show cross-sectional views illustrating steps of making a typical metal oxide metal (MOM) capacitor 614.

In cross-sectional view 600 of FIG. 6A, a first conductive layer 604 that has been deposited onto a substrate 602 is patterned. The first conductive layer 604 may be deposited by any conventional deposition process such as sputtering or chemical vapor deposition (CVD). A typical exposure-and-etch process with photoresist and a photolithography mask can also be used to pattern the first conductive layer 604.

In cross-sectional view 610 of FIG. 6B, an interconnect 606 is deposited on the first conductive layer 604 and then patterned. A dielectric layer 608 is then deposited over the interconnect 606 and the first conductive layer 604. The interconnect may be deposited and patterned in the same manner that the first conductive layer 604 is deposited and patterned, as described above. The dielectric layer 608 may be deposited by a spin-coating process, chemical vapor deposition (CVD), physical vapor deposition (PVD), sputtering, and/or evaporation. The dielectric layer 608 can also be patterned by any photolithography exposure and etching process. The etching may include any dry plasma etching process, wet chemical etching process, or other like etching process.

In cross-sectional view 620 of FIG. 6C, a second conductive layer 612 is deposited on the interconnect 606 and then patterned. A dielectric layer 608 is then deposited so that the dielectric layer 608 is planar with a top surface of the second conductive layer 612. As a result, the metal oxide metal (MOM) capacitor 614 is formed. The second conductive layer 612 may be deposited and patterned in the same manner that the first conductive layer 604 is deposited and patterned, as described above. Problems and downfalls of the MOM capacitor 614 have been explained above, with reference to FIG. 3B, for example. The process for fabricating the MOM capacitor 614 is also shown just to emphasize its complexity, the number of steps it takes to fabricate, and its resource consumption.

FIGS. 6D-6F show cross-sectional views illustrating steps of making a typical vertical metal insulator metal (MIM) capacitor 616.

In cross-sectional view 630 of FIG. 6D, a first conductive layer 604 that has been deposited onto a substrate 602 is patterned. The first conductive layer 604 may be deposited by any conventional deposition process such as sputtering or chemical vapor deposition (CVD). A typical exposure-and-etch process with photoresist and a photolithography mask can also be used to pattern the first conductive layer 604.

In cross-sectional view 640 of FIG. 6E, a dielectric layer 608 is deposited onto the first conductive layer 604 and then patterned. The dielectric layer 608 may be deposited by a spin-coating process, chemical vapor deposition (CVD), physical vapor deposition (PVD), sputtering, and/or evaporation. The dielectric layer 608 can also be patterned by any photolithography exposure and etching process. The etching may include any dry plasma etching process, wet chemical etching process, or other like etching process.

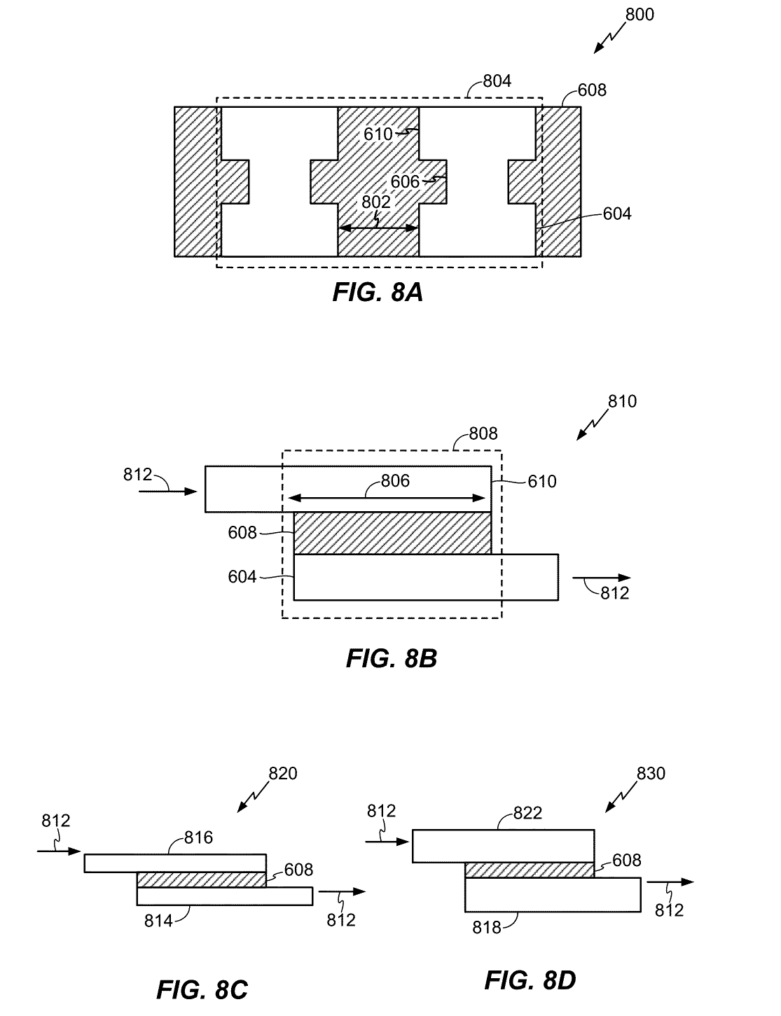

In cross-sectional view 650 of FIG. 6F, a second conductive layer 612 is deposited onto the dielectric layer 608 and then patterned. The second conductive layer 612 may be deposited and patterned in the same manner that the first conductive layer 604 is deposited and patterned, as described above. The first conductive layer 604 hangs to the right of the dielectric layer 608 and the second conductive layer 612 has a left hangover compared to the dielectric layer 608, as shown in FIG. 6F. As a result, a vertical metal insulator metal (MIM) capacitor 614 is formed. Problems and downfalls of the vertical MIM capacitor 616 will be explained in more detail with reference to FIGS. 8B and 8C. Parts of the problems of the vertical MIM capacitor 616 have already been explained with reference to FIGS. 1, 2 and 3A. The process for fabricating the vertical MIM capacitor 616 is also shown just to emphasize its complexity, the number of steps it takes to fabricate, and its resource consumption.

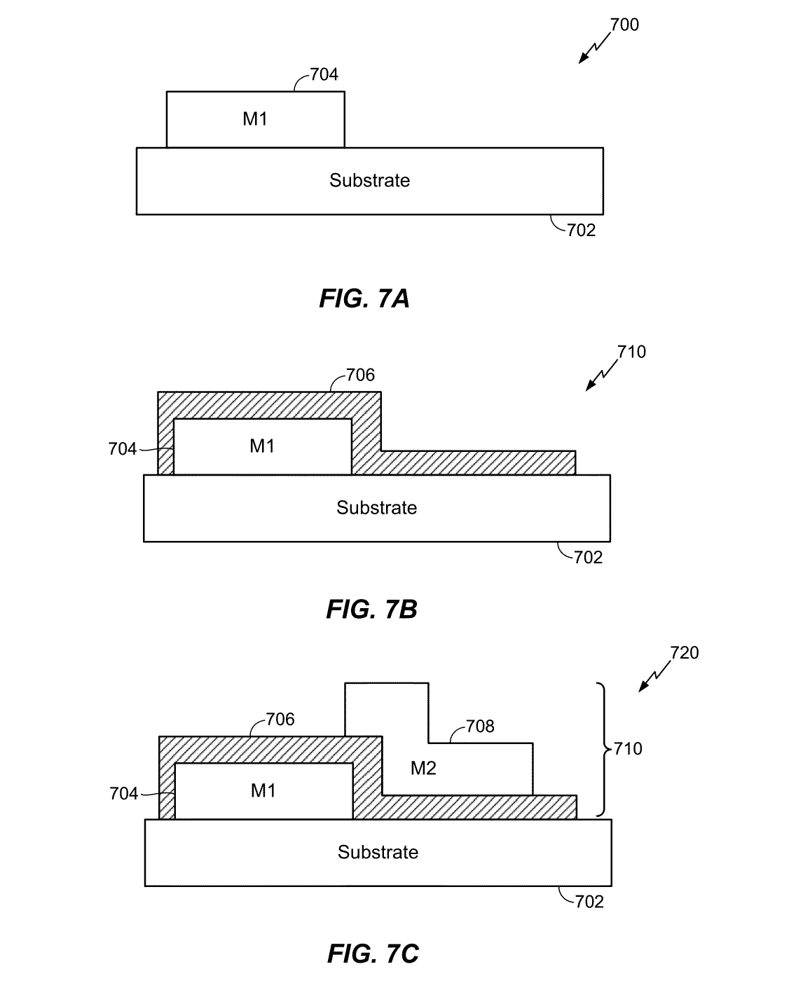

FIGS. 7A-7C show cross-sectional views illustrating steps of making a lateral metal insulator metal (MIM) capacitor 712, according to one aspect of the disclosure.

In cross-sectional view 700 of FIG. 7A, a first conductive layer 704 that has been deposited on a substrate 702 is patterned. The first conductive layer 704 may be deposited by electroplating, chemical vapor deposition (CVD), and/or physical vapor deposition (PVD), such as sputtering or evaporation. The first conductive layer 704 may then be patterned by an exposure and etching process using photoresist and a photolithography mask. The etching process may include dry plasma etching, wet chemical etching, or like etching process. The substrate 702 may be made of glass or other materials such as silicon (Si), gallium arsenide (GaAs), indium phosphide (InP), silicon carbide (SiC), sapphire (Al2O3), quartz, silicon on insulator (SOI), silicon on sapphire (SOS), high resistivity silicon (HRS), aluminum nitride (AlN), a plastic substrate, a laminate, or a combination thereof.

In cross-sectional view 710 of FIG. 7B, a dielectric layer 706 is deposited over the patterned first conductive layer 704. The dielectric layer 706 may be deposited by a spin-coating process, chemical vapor deposition (CVD), physical vapor deposition (PVD), sputtering, and/or evaporation. It is to be noted that the dielectric layer 706 is simply deposited (one process step) in the process to fabricate a lateral MIM capacitor 712, and does not require additional process steps such as patterning/etching and photoresist deposition, etching and stripping (such as the additional process steps performed in FIGS. 6D-6F), or depositing additional dielectric layers (such as the additional process steps performed in FIGS. 6A-6C).

In cross-sectional view 720 of FIG. 7C, a second conductive layer 708 that has been deposited on the dielectric layer 706 is patterned. The second conductive layer 708 may be deposited and patterned in the same manner that the first conductive layer 704 is deposited and patterned, as described above. As a result, a lateral metal insulator metal (MIM) capacitor 712 is formed. The process steps of fabricating a lateral MIM capacitor 712 is shown in FIGS. 7A-7C to emphasize the simplicity and robustness of the process, the lower number of process steps, and its conservation of resources and area.

FIG. 8A shows a more detailed cross-sectional view of a typical metal oxide metal (MOM) capacitor 804. The MOM capacitor 804 includes a first conductive layer 604, an interconnect 606, a second conductive layer 612, and dielectric layer 608. Because a capacitor gap 802 is large, there is low capacitance in the MOM capacitor 804. Also, minimum trace spacing in the MOM capacitor 804 may also lead to a lower capacitance value. Furthermore, the presence of the interconnects 606 may degrade the Q, or quality factor of the MOM capacitor 804.

FIG. 8B shows a more detailed cross-sectional view of a typical vertical metal insulator metal (MIM) capacitor 808. The vertical MIM capacitor 808 includes a first conductive layer 604, a dielectric layer 608, a second conductive layer 612, and a plate length 806. Because the plate length 806 is long in the vertical MIM capacitor 808, there is a high resistive loss and a large parasitic inductance. Current flow arrows 812 also represent the direction of current flow through the top and bottom plates and other components of the vertical MIM capacitor 808.

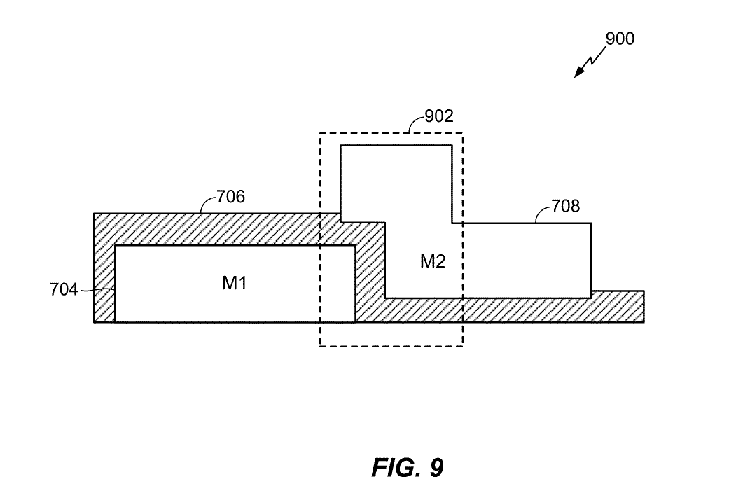

FIGS. 8C-8D show cross-sectional views of typical vertical metal insulator metal (MIM) capacitors with current flow. In FIG. 8C, a thin vertical metal insulator metal (MIM) capacitor 820 includes a first thin conductive layer 814, a dielectric layer 608 and a second thin conductive layer 816. In one configuration, the thickness of the first thin conductive layer 814 and the second thin conductive layer 816 is around 3 μm. In FIG. 8D, a thick vertical MIM capacitor 830 includes a first thick conductive layer 818, a dielectric layer 608 and a second thick conductive layer 822. In one configuration, the thickness of the first thick conductive layer 818 and the second thick conductive layer 822 is around 10 μm. Current flow arrows 812 represent the direction of current flow through the thin vertical MIM capacitor 820 and the thick vertical MIM capacitor 830. In one configuration, the thickness of the first conductive layer 404 and the second conductive layer 406 of the lateral MIM capacitor 410 of FIG. 4, or the thickness of the first conductive layer 704 and the second conductive layer 708 of FIG. 7C and FIG. 9 is around 10 μm as well.

FIG. 9 shows a more detailed cross-sectional view of a lateral metal insulator metal (MIM) capacitor 902, according to one aspect of the disclosure. Advantages of the lateral MIM capacitor 902 include ultra-low resistance or resistive loss as well as very low levels of parasitic inductance. Also the capacitance density for the lateral MIM capacitor 902 is dense and compact, and has a much smaller capacitor gap than the capacitor gap 802 of the MOM capacitor 804. Therefore, the capacitance value for the lateral MIM capacitor 902 is much greater and higher than most conventional MIM capacitor or MOM capacitor designs.

The sidewall capacitance, or the capacitance between the dielectric layer 706 and the sidewalls of the first conductive layer 704 or the second conductive layer 708, is also greater than a surface capacitance, or the capacitance between the dielectric layer 706 and the top surface of the first conductive layer 704 or the bottom surface of the second conductive layer 708, as shown in FIG. 9.

In terms of quality factor versus frequency, the thin vertical MIM capacitor 820 may start out at a low Q factor value such as around 200 at a frequency of 0.8 GHz and slowly slope downwards with increasing frequency, if plotted as a curve. The thick vertical MIM capacitor 830 may also start out at a low Q factor value such as around 300 at a frequency of 0.8 GHz and also slowly slope downwards with increasing frequency, if plotted like a curve. The lateral MIM capacitor, however, may start out at a high Q factor value (e.g., 1100 at a frequency of 0.8 GHz) and slowly slope downwards with increasing frequency, if plotted like a curve.

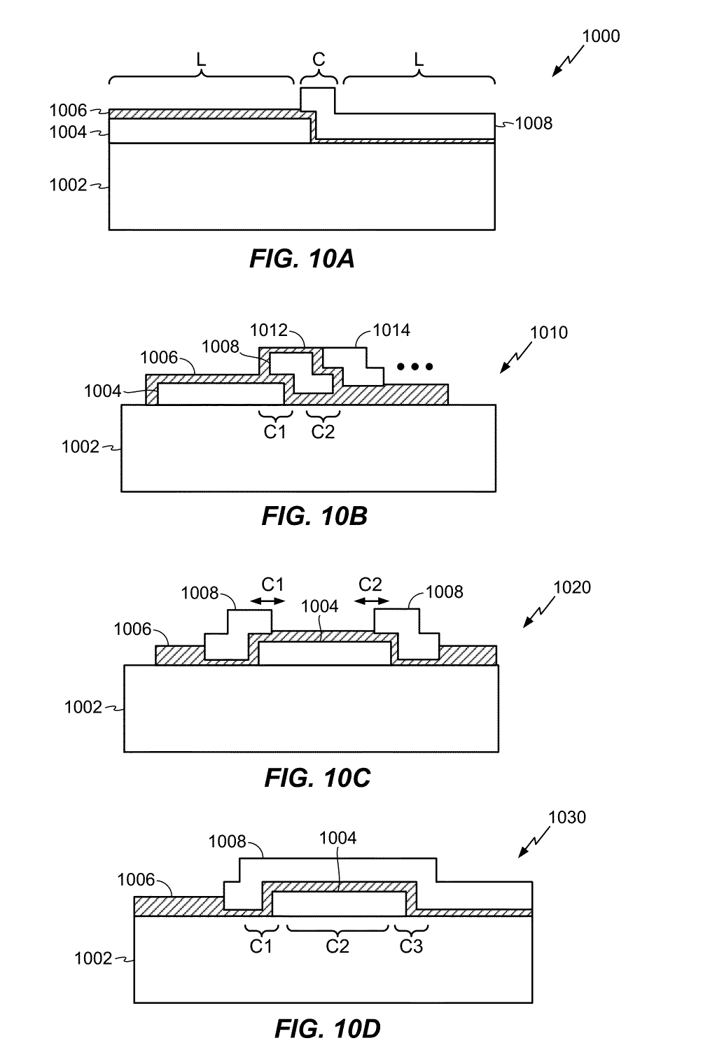

FIG. 10A shows a device 1000 with a low parasitic inductor-capacitor transition structure, according to one aspect of the disclosure. The device 1000 includes a substrate 1002, a first conductive layer 1004, a dielectric layer 1006 and a second conductive layer 1008. In the device 1000, the region marked “L” is an inductor connected directly to the lateral MIM capacitor marked by “C.” The direct connection between “L” and “C”, without any vias or parasitic elements between the capacitor and inductor leads to a high performance circuit with little or no loss. The configuration of the device 1000 provides a greater reduction in overall parasitic inductance and resistance of a lateral MIM capacitor.

FIG. 10B shows a device 1010 with a series of multiple lateral metal insulator metal (MIM) capacitors, according to one aspect of the disclosure. The device 1010 includes a substrate 1002, a first conductive layer 1004, a first dielectric layer 1006, a second conductive layer 1008, a second dielectric layer 1012 and a third conductive layer 1014, which can be expanded into a third dielectric layer and a fourth conductive layer, and so on and so forth, as reflected by the ellipsis. The configuration of device 1010 creates a series of multiple lateral MIM capacitors. As seen in FIG. 10B, first lateral MIM capacitor C1 includes the first dielectric layer 1006 sandwiched in between the first conductive layer 1004 and the second conductive layer 1008. A second lateral MIM capacitor C2 includes the second dielectric layer 1012 sandwiched in between the second conductive layer 1008 and the third conductive layer 1014. The third lateral MIM capacitor (C3) and onwards can be created indefinitely by depositing more sets of dielectric layers followed by conductive layers. For example, if N additional series lateral MIM capacitors are to be created, a counter system with a simple counter and logic function could be created to fabricate a set number of lateral MIM capacitors.

An example of such a counter system is as follows: (1) Identifying a most recent patterned conductive layer as the patterned second conductive layer and setting a variable, N, to zero. (2) Depositing an additional dielectric layer over the most recent patterned conductive layer. (3) Depositing an additional conductive layer over the deposited additional dielectric layer. (4) Patterning the deposited additional conductive layer and making it the most recent patterned conductive layer. (5) Incrementing N. (6) Determining if N is equal to the desired number of lateral MIM capacitors to be fabricated in series. And, (7) if not, returning to depositing an additional dielectric layer over the most recent patterned conductive layer.

Creating more lateral MIM capacitors in series also leads to reduced electrostatic loss or electrostatic resistance, which in turn leads to a higher electrostatic discharge (ESD) rating.

FIG. 10C shows a device 1020 with at least two lateral metal insulator metal (MIM) capacitors in parallel, according to one aspect of the disclosure. The device 1020 includes a substrate 1002, a first conductive layer 1004, a dielectric layer 1006 and a second conductive layer 1008. As can be seen in FIG. 10C, there are two lateral MIM capacitors C1 and C2, which are arranged in parallel. Being able to fabricate lateral MIM capacitors in parallel also leads to reduced process variation. Series lateral MIM capacitors can also be added to C1 and C2 following the process shown in FIG. 10B, by depositing and patterning additional dielectric and conductive layers.

An example process to create device 1020 includes: etching a middle portion of the deposited second conductive layer down to the dielectric layer to form two separate lateral MIM capacitors in parallel, then performing further pattern development on each of the two separate lateral MIM capacitors. Performing further pattern development may mean that for each of the two separate lateral MIM capacitors, the deposited second conductive layer is etched down to the dielectric layer on either side to further define side boundaries.

FIG. 10D shows a device 1030 with a lateral and a vertical metal insulator metal (MIM) capacitor in one structure, according to one aspect of the disclosure. The device 1030 includes a substrate 1002, a first conductive layer 1004, a dielectric layer 1006 and a second conductive layer 1008. As can be seen in FIG. 10D, there are two lateral MIM capacitors C1 and C3, and a vertical MIM capacitor C2. Therefore, device 1030 shows that the process used to fabricate lateral MIM capacitors can be also used to form other types of capacitors (such as vertical MIM capacitors, other types of MIM capacitors and even metal oxide metal (MOM) capacitors). Series lateral MIM capacitors may also be added to device 1030 following the process shown in FIG. 10B. By combining the lateral MIM capacitor design with other capacitor designs as device 1030 does, devices can be fabricating having specifically tailored capacitance values or Q factor properties, or be used for specific applications.

An example process to create device 1030 may include etching a side region of the deposited second conductive layer down to the dielectric layer to form a lateral MIM capacitor and a vertical MIM capacitor.

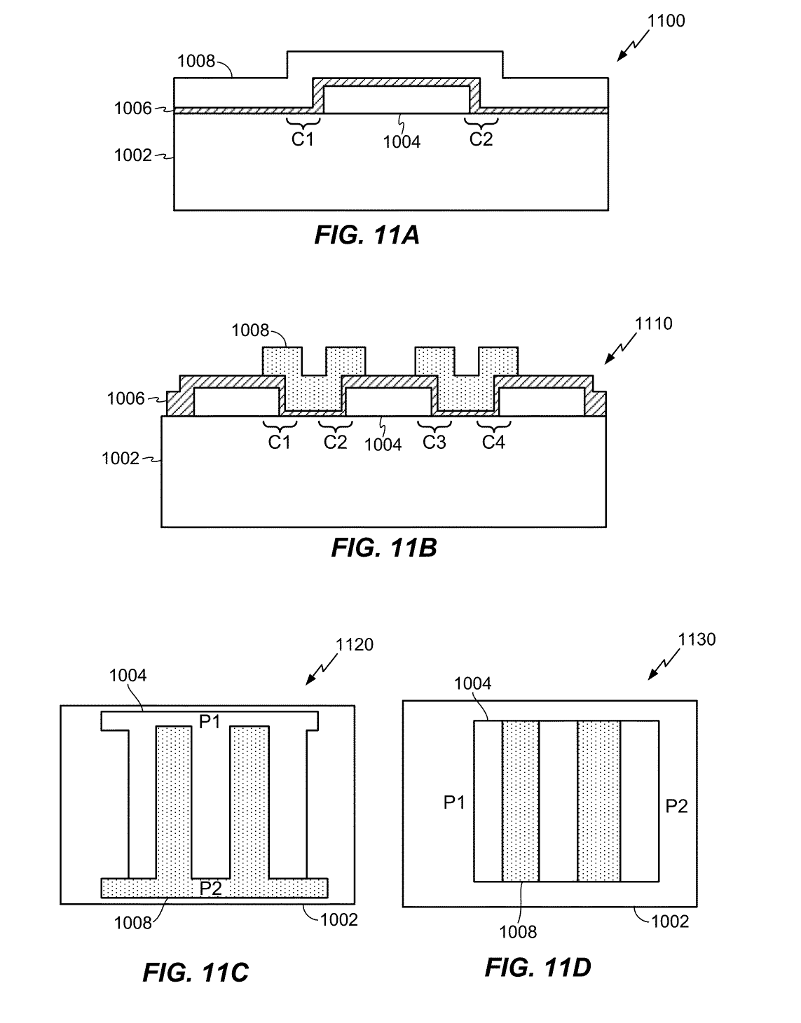

FIG. 11A shows a device 1100 with an under/overpass metal insulator metal (MIM) capacitor, according to one aspect of the disclosure. The device 1100 includes a substrate 1002, a first conductive layer 1004, a dielectric layer 1006 and a second conductive layer 1008. Two lateral MIM capacitors can be seen in device 1100: C1 and C2. One advantage of the device 1100, which uses the “under/overpass” fabrication technique, is that there hardly needs to be any patterning. The only patterning step that may be required is the patterning for the first conductive layer 1004. Then, the dielectric layer 1006 is simply deposited over the patterned first conductive layer 1004 without any additional patterning, and the second conductive layer 1008 is merely deposited over the deposited dielectric layer 1006, also without performing any additional patterning. Therefore, the process used to fabricate device 1100 may be the quickest and efficient process that can be used to fabricate lateral MIM capacitors.

An example process to create device 1110 may include etching a set of gaps down to the substrate in the first conductive layer, and then etching the deposited second conductive layer into regions filling the set of gaps to form a set of finger lateral MIM capacitors.

FIGS. 11B-11D show different views of a device with a multi-finger lateral metal insulator metal (MIM) capacitor for both series and parallel connections, according to one aspect of the disclosure. The device 1110 includes a substrate 1002, a first conductive layer 1004, a dielectric layer 1006 and a second conductive layer 1008. Four lateral MIM capacitors can be seen in device 1110: C1, C2, C3 and C4. Therefore device 1110 can be viewed as a multi-finger lateral MIM capacitor, each finger being a different lateral MIM capacitor. Top views 1120 and 1130 are views of device 1110 from different sides. The multi-finger configuration may also be implemented for both series and parallel sets of lateral MIM capacitors. Such a multi-finger capacitor structure also maintains a high Q, or quality factor, because no interconnects are used, and many lateral MIM capacitors can be created.

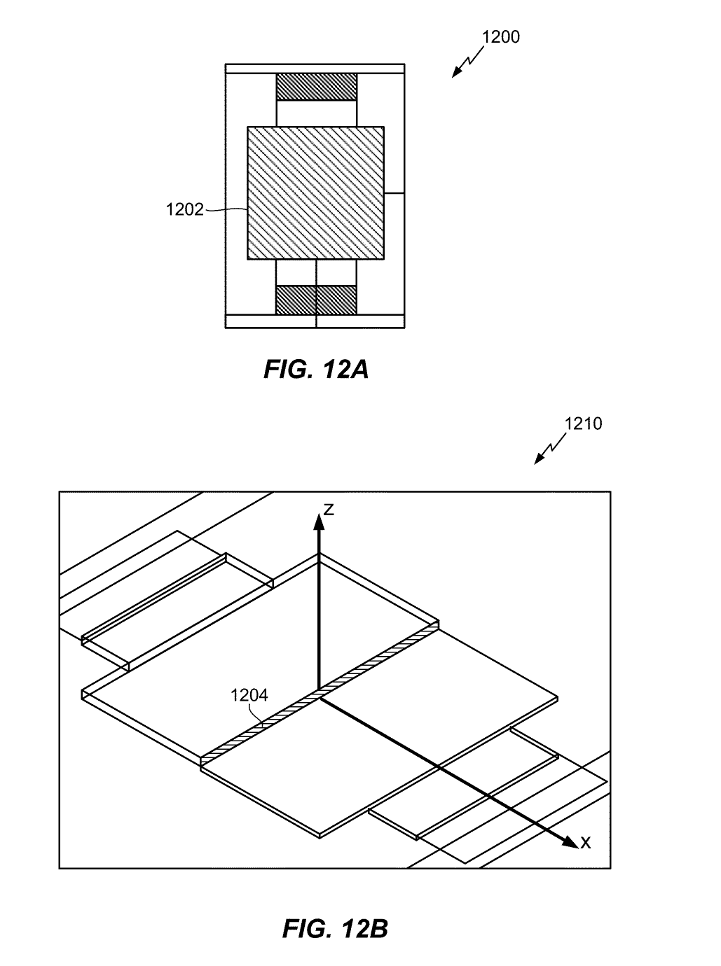

FIG. 12A is a top view 1200 illustrating the area of a typical planar metal insulator metal (MIM) capacitor 1202. The typical planar MIM capacitor 1202 is fabricated with a conventional MIM capacitor design, such as the designs discussed above. Therefore, the typical planar MIM capacitor 1202 may exhibit a low Q (or quality) factor, have low capacitance and a low capacitance density (e.g., large capacitor gaps and reduced trace spacing), take up too much area, have high levels of series resistance, and also high parasitic inductance. In one configuration, the typical planar MIM capacitor 1202 has a Q value of 30 at a frequency of 2 GHz, and a total area of 1000 μm².

FIG. 12B is a three-dimensional view 1210 illustrating the area of a lateral metal insulator metal (MIM) capacitor 1204, according to one aspect of the disclosure. The lateral MIM capacitor 1204 is fabricated with the lateral MIM capacitor fabrication process discussed above. Therefore, the lateral MIM capacitor 1204 may have a high Q, factor, high capacitance and capacitance density (e.g., small capacitor gaps), have smaller area, ultra-low series resistance, and also ultra-low parasitic inductance. In one configuration, the lateral MIM capacitor 1204 has a Q value of 250 at a frequency of 2 GHz, and a total area of just 3.5 μm².

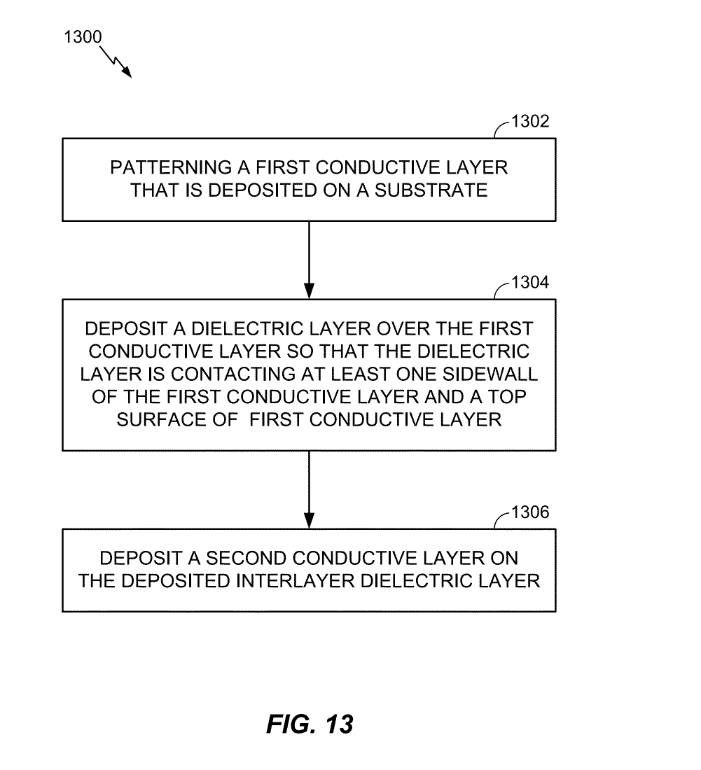

FIG. 13 is a process flow diagram 1300 illustrating a process to fabricate a lateral metal insulator metal (MIM) capacitor, according to one aspect of the disclosure. In block 1302, a first conductive layer (e.g., the first conductive layer 404 or the first conductive layer 704) deposited on a substrate (e.g., the substrate 402 or the substrate 702) is patterned. This is also shown in the cross-sectional view 700 of FIG. 7A. In block 1304, a dielectric layer (e.g., the dielectric layer 408 or the dielectric layer 706) is deposited on the first conductive layer so that the dielectric layer is on the sidewall(s) of the first conductive layer and a first surface of the first conductive layer adjacent to the sidewall(s) of the first conductive layer. In block 1306, a second conductive layer (e.g., the second conductive layer 406 or the second conductive layer 708) is deposited on a portion of the dielectric layer that is on the at least one sidewall (e.g., 422) and on a portion of the dielectric layer covering a portion of the first surface (e.g., 420) of the first conductive layer. For example, as shown in FIG. 4, the second conductive layer is only on a sidewall portion 428 and a bottom surface portion 424 of the dielectric layer that is on the surface of the substrate 402.

In one aspect of the disclosure, a lateral metal insulator metal (MIM) capacitor is disclosed that includes first means for conducting. The capacitor also includes a dielectric layer on at least one sidewall and a first surface of the first conducting means adjacent to the sidewall(s). The capacitor also includes second means for conducting on a portion of the dielectric layer that is on the sidewall and on a portion of the dielectric layer the sidewall that covers a portion of the second surface of the first conducting means. A sidewall capacitance is also greater than a surface capacitance. In one configuration, the first conducting means is the first conductive layer 404 or the first conductive layer 704, and the second conducting means is the second conductive layer 406 or the second conductive layer 708.

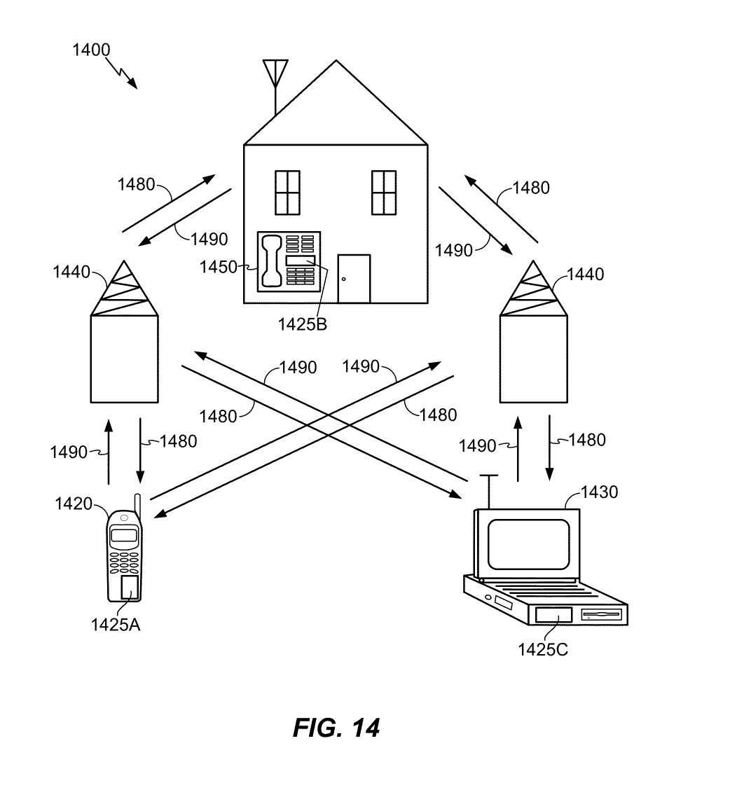

FIG. 14 is a block diagram showing an exemplary wireless communication system 1400 in which an aspect of the disclosure may be advantageously employed. For purposes of illustration, FIG. 14 shows three remote units 1420, 1430, and 1450 and two base stations 1440. It will be recognized that wireless communication systems may have many more remote units and base stations. Remote units 1420, 1430, and 1450 include IC devices 1425A, 1425C, and 1425B that include the disclosed devices (e.g. lateral metal insulator metal (MIM) capacitors). It will be recognized that other devices may also include the disclosed devices (e.g. lateral MIM capacitors), such as the base stations, switching devices, and network equipment. FIG. 14 shows forward link signals 1480 from the base station 1440 to the remote units 1420, 1430, and 1450 and reverse link signals 1490 from the remote units 1420, 1430, and 1450 to base stations 1440.

In FIG. 14, remote unit 1420 is shown as a mobile telephone, remote unit 1430 is shown as a portable computer, and remote unit 1450 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or other devices that store or retrieve data or computer instructions, or combinations thereof. Although FIG. 14 illustrates remote units according to the aspects of the disclosure, the disclosure is not limited to these exemplary illustrated units. Aspects of the disclosure may be suitably employed in many devices, which include the disclosed lateral MIM capacitor devices.

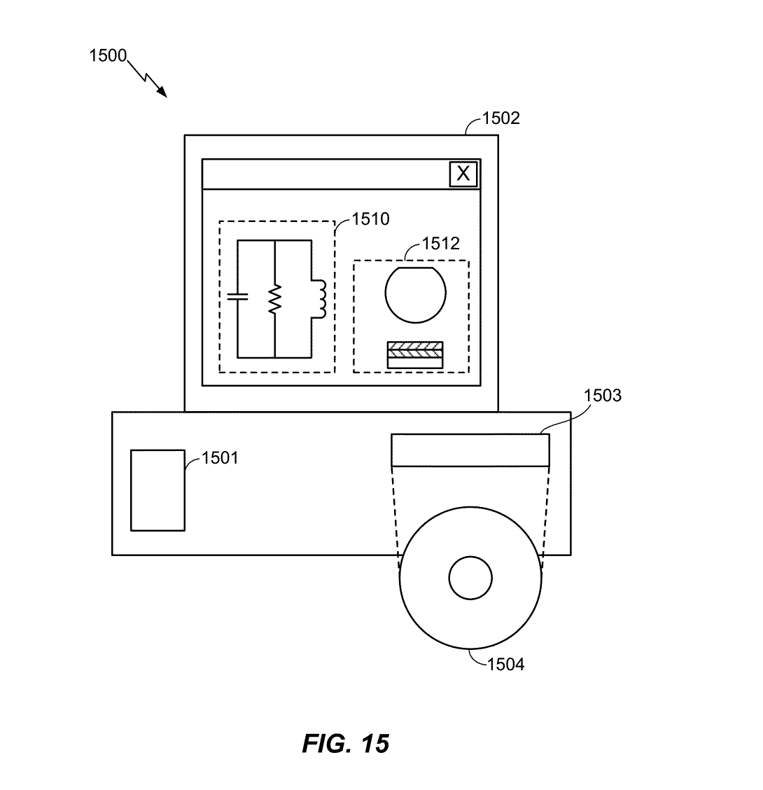

FIG. 15 is a block diagram illustrating a design workstation used for circuit, layout, and logic design of a semiconductor component, such as the lateral MIM capacitor devices disclosed above. A design workstation 1500 includes a hard disk 1501 containing operating system software, support files, and design software such as Cadence or OrCAD. The design workstation 1500 also includes a display 1502 to facilitate design of a circuit 1510 or a semiconductor component 1512 such as the disclosed device (e.g., a lateral MIM capacitor). A storage medium 1504 is provided for tangibly storing the circuit design 1510 or the semiconductor component 1512. The circuit design 1510 or the semiconductor component 1512 may be stored on the storage medium 1504 in a file format such as GDSII or GERBER. The storage medium 1504 may be a CD-ROM, DVD, hard disk, flash memory, or other appropriate device. Furthermore, the design workstation 1500 includes a drive apparatus 1503 for accepting input from or writing output to the storage medium 1504.

Data recorded on the storage medium 1504 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1504 facilitates the design of the circuit design 1510 or the semiconductor component 1512 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A lateral metal insulator metal (MIM) capacitor, comprising:
a first conductive plate;
at least one dielectric layer on at least one sidewall and a first surface of the first conductive plate adjacent to the at least one sidewall of the first conductive plate; and
a second conductive plate on a portion of the at least one dielectric layer that is on the at least one sidewall and on a portion of the at least one dielectric layer covering a portion of the first surface of the first conductive plate, a sidewall capacitance being greater than a surface capacitance.

2. The lateral MIM capacitor of claim 1, in which the first conductive plate and/or the second conductive plate is a portion of an inductor.

3. The lateral MIM capacitor of claim 1, further comprising:
a second dielectric layer on the at least one sidewall and a second surface of the second conductive plate adjacent to the at least one sidewall of the second conductive plate; and
a third conductive plate on a portion of the second dielectric layer that is on the at least one sidewall and a portion of the second dielectric layer covering the second surface of the second conductive plate.

4. The lateral MIM capacitor of claim 1, further comprising:
another dielectric layer on another sidewall and another surface of the first conductive plate adjacent to the another sidewall of the first conductive plate; and
a third conductive plate on a portion of the another dielectric layer that is on the another sidewall and on a portion of the another dielectric layer covering the another surface of the first conductive plate.

5. The lateral MIM capacitor of claim 1 incorporated into at least one of a music player, a video player, an entertainment unit, a navigation device, a communications device, a personal digital assistant (PDA), a fixed location data unit, and a computer.

6. A lateral metal insulator metal (MIM) capacitor, comprising:
first means for conducting;
at least one dielectric layer on at least one sidewall and a first surface of the first conducting means adjacent to the at least one sidewall of the first conducting means; and
second means for conducting on a portion of the at least one dielectric layer that is on the at least one sidewall and on a portion of the at least one dielectric layer covering a portion of the first surface of the first conducting means, a sidewall capacitance being greater than a surface capacitance.

7. The lateral MIM capacitor of claim 6, in which the first conducting means and/or the second conducting means is a portion of an inductor.

8. The lateral MIM capacitor of claim 6, further comprising:
a second dielectric layer on the at least one sidewall and a second surface of the second conducting means adjacent to the at least one sidewall of the second conducting means; and
third means for conducting on a portion of the second dielectric layer that is on the at least one sidewall and a portion of the second dielectric layer covering the second surface of the second conducting means.

9. The lateral MIM capacitor of claim 6, further comprising:
another dielectric layer on another sidewall and another surface of the first conducting means; and
third means for conducting on a portion of the another dielectric that is on the another sidewall and on a portion of the another dielectric layer covering the another surface of the first means for conducting.

10. The lateral MIM capacitor of claim 6 incorporated into at least one of a music player, a video player, an entertainment unit, a navigation device, a communications device, a personal digital assistant (PDA), a fixed location data unit, and a computer.

11. A back end of line processing method to fabricate a lateral metal insulator metal (MIM) capacitor, comprising:
patterning a first conductive layer that is deposited on a substrate;
depositing a dielectric layer on the first conductive layer so that the dielectric layer is on at least one sidewall of the first conductive layer and a first surface of the first conductive layer adjacent to the at least one sidewall of the first conductive layer;
depositing a second conductive layer on a portion of the dielectric layer that is on the at least one sidewall and on a portion of the dielectric layer covering a portion of the first surface of the first conductive layer, a sidewall capacitance being greater than a surface capacitance.

12. The method of claim 11, further comprising patterning the second conductive layer.

13. The method of claim 12, further comprising:
identifying a most recent patterned conductive layer as the second conductive layer and setting a variable, N, to zero;
depositing an additional dielectric layer on the most recent patterned conductive layer;
depositing an additional conductive layer on the additional dielectric layer;
patterning the additional conductive layer and identifying it as the most recent patterned conductive layer;
incrementing N;
determining if N is equal to a predetermined number of lateral MIM capacitors to be fabricated in series; and
if not, returning to depositing the additional dielectric layer on the most recent pattered conductive layer.

14. The method of claim 12, in which patterning the deposited second conductive layer comprises:
etching another portion of the second conductive layer to expose the dielectric layer to enable parallel formation of two separate lateral MIM capacitors;
performing further pattern development on each of the two separate lateral MIM capacitors.

15. The method of claim 14, in which the performing further pattern development on each of the two separate lateral MIM capacitors comprises:
for each of the two separate lateral MIM capacitors, etching the second conductive layer to expose the dielectric layer on either side to further define side boundaries.

16. The method of claim 12, in which patterning the deposited second conductive layer comprises:
etching a side region of the second conductive layer to expose to the dielectric layer to form a lateral MIM capacitor and a vertical MIM capacitor.

17. The method of claim 12, in which patterning the first conductive layer comprises etching a plurality of openings to expose the substrate, and in which patterning the deposited second conductive layer comprises:
etching the second conductive layer into regions filling the plurality of openings to form a plurality of finger lateral MIM capacitors.

18. The method of claim 11, further comprising incorporating the lateral MIM capacitor into at least one of a music player, a video player, an entertainment unit, a navigation device, a communications device, a personal digital assistant (PDA), a fixed location data unit, and a computer.
